(19) United States
(12) Patent Application Publication
(10) Pub. No.: US 2006/0156204 A1
(43) Pub. Date: Jul. 13, 2006

(54) Context-adaptive variable length coding apparatus and methods

(75) Inventors: Kyung-koo Lee, Seoul (KR); Jung-sun Kang, Seoul (KR); Jin-hyun Cho, Gyeonggi-do (KR); Seung-sick Jun, Gyeonggi-do (KR); Chang-hyun Yim, Gyeonggi-do (KR); Yun-kyoung Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/331,743

(22) Filed: Jan. 13, 2006

(30) Foreign Application Priority Data
Jan. 13, 2004 (KR) 10-2005-0003181

(51) Int. Cl. H03M 13/00

(52) U.S. Cl. 714/779

(57) ABSTRACT

A context-adaptive variable length coding (VLC) apparatus includes a coefficient information generation unit configured to generate coefficient information used for coding variable-length-code coefficients for a selected block of a selected macroblock of image data that is read out in response to an information generation control signal, a bit data generation unit configured to operate in response to a bit generation control signal, and to code coefficients of a previous block, which is read out just before the selected block, using coefficient information of the previous block, and a control unit configured to generate the information generation control signal and the bit generation control signal, and to cause the coefficient information generation unit and the bit data generation unit to operate at in parallel using the information generation control signal and the bit generation control signal. A method of variable-length coding coefficients of image data is also provided.

### CLAIM OF PRIORITY

This application claims the benefit of and priority to Korean Patent Application No. 10-2005-0003181, filed on Jan. 13, 2005, in the Korean Intellectual Property Office, the disclosure of which is incorporated herein in its entirety by reference.

### FIELD OF THE INVENTION

The present invention relates to context-adaptive variable length coding (VLC). In particular, the present invention relates to context-adaptive VLC apparatus and methods which perform context-adaptive VLC on coefficients into which image data is converted.

### BACKGROUND OF THE INVENTION

In a moving picture compression method specified in a standard, such as H.264 or ISO MPEG-4 Part 10, a plurality of moving image data are converted into coefficients based on information of the image data, and then the coefficients are coded.

The coefficients into which the moving image data is converted can be coded using a variable length coding (VLC) method, and particularly, a context-adaptive VLC (CAVLC) method.

In a VLC method, image data is divided into a plurality of macroblocks and then is processed in units of the macroblocks, rather than being processed as a whole.

A macroblock is a set of M×N pixels. In general, a macroblock used in a moving picture coding method may have a size of 16×16 pixels.

In a context-adaptive VLC method, which is used in H.264 or MPEG-4 Part 10-based moving picture compression technology, coefficients are coded in units of 16×16 macroblocks.

Specifically, in the context-adaptive VLC method, a coding mode is determined based on whether DC coefficients of each block are to coded. Thereafter, a macroblock is divided into a plurality of blocks, e.g., a plurality of 4×4 blocks, and coefficients of each of the blocks are variable-length-coded in the determined coding mode.

FIG. 1 is a flowchart of a conventional context-adaptive VLC method. Referring to FIG. 1, in operation S101, a total coefficient number TC is calculated by reading a block to be coded (hereinafter referred to as a current block) following a zigzag course. The total coefficient number TC is coded with reference to a predetermined total coefficient table, and then a trailing ones number T1 is calculated.

Here, the total coefficient number TC is the number of coefficients having a value other than 0, and the trailing ones number T1 is the number of trailing ones in the current block, i.e., the number of consecutive coefficients having a value of +1 or −1 (i.e., an absolute value of 1) which have been most recently read out from the current block. The trailing ones number T1 cannot exceed 3. In other words, even if three or more consecutive coefficients having an absolute value of 1 are read out from the current block, the trailing ones number T1 is 3.

In addition, the total coefficient table is selected based on the total coefficient number TC of the current block and total coefficient numbers of blocks adjacent to the current block, e.g., blocks at the left and upper sides of the current block.

In operation S103, the signs of the trailing ones of the current block are coded. For example, if a trailing one of the current block has a value of +1, the sign of the trailing one, i.e., (+), is coded as 0. If the trailing one of the current block has a value of −1, the sign of the coefficient, i.e., (−), is coded as 1.

In operation S105, the coefficients of the current block are obtained once again by reading the current block following an inverse zigzag course, and then the values of some of the coefficients having a value other than 0, i.e., level values LEVEL, are coded with reference to a predetermined level table.

In operation S107, a total number of zeros T0 is coded. The total zeros number T0 is the number of coefficients having a value of 0 before a coefficient having a value other than 0 which was most recently read out from the current block, when the coefficients of the current block are read following a zigzag course.

In operation S109, a run value RUN of each of the levels of the current block is coded. Here, the run value RUN is the number of coefficients having a value of 0 between coefficients having a value of other than 0, when the coefficients of the current block are read following a zigzag course. Accordingly, each of the levels has one run value RUN.

As described above, in a conventional context-adaptive VLC method, coefficients of a current block can be coded by generating and coding coefficient information, e.g., a total coefficient number, a trailing ones number, level values, run values, and a total zeros number of the current block. However, it may take a considerable amount of time to code the coefficients of a current block in the above-described manner, because the coding of the coefficients of the current block may require reading of the current block at least two times following a zigzag course and then an inverse zigzag course.

### SUMMARY OF THE INVENTION

Some embodiments of the present invention provide a context-adaptive variable length coding (VLC) apparatus, which is configured to perform, in parallel, an operation of generating coefficient information for coding coefficients of a block of data by reading coefficients from the block following an inverse zigzag course, and an operation of generating bit data with reference to the generated coefficient information.

Some embodiments of the present invention may also provide a context-adaptive VLC method including performing in parallel an operation of generating coefficient information for coding coefficients of a block of data by reading coefficients from the block following an inverse zigzag course, and an operation of generating bit data with reference to the generated coefficient information.

According to some embodiments of the present invention, there is provided a context-adaptive variable length coding (VLC) apparatus that is configured to divide image data into a plurality of macroblocks, and to divide each of the macroblocks into a plurality of blocks. The apparatus is further configured to encode coefficients of each of the blocks of each of the macroblocks using variable-length-codes.

A context-adaptive VLC apparatus may include a coefficient information generation unit, which is configured to generate coefficient information for coding coefficients of a current block of data that is read out in response to an information generation control signal, a bit data generation unit, which is configured to operate in response to a bit generation control signal, and which is configured to code coefficients of a previous block, which is read out just before the current block being read out, in response to coefficient information of the previous block, and a control unit, which is configured to generate the information generation control signal and the bit generation control signal. The coefficient information generation unit and the bit data generation unit are caused to operate in overlapping time intervals using the information generation control signal and the bit generation control signal.

According to further embodiments of the present invention, a context-adaptive VLC method includes dividing image data into a plurality of macroblocks, dividing each of the macroblocks into a plurality of blocks, and variable-length-coding coefficients of each of the blocks of each of the macroblocks. The context-adaptive VLC method may include generating coefficient information for coding coefficients of a block currently being read out in response to an information generation control signal, and coding coefficient information of a previous block generated in advance by the coefficient information generation unit in response to a bit generation control signal, wherein generating the coefficient information of the current block and coding of the coefficient information of the previous block are performed in overlapping time intervals.

### BRIEF DESCRIPTION OF THE DRAWINGS

The above and other features and advantages of the present invention will become more apparent by describing in detail exemplary embodiments thereof with reference to the attached drawings in which:

FIG. 1 is a flowchart of a conventional context-adaptive variable length coding (VLC) method;

FIG. 2 is a block diagram of a context-adaptive VLC apparatus according to some embodiments of the present invention;

FIG. 3 is a block diagram of a control unit of FIG. 2;

FIG. 4 is a block diagram of a coefficient information generation unit of FIG. 2;

FIG. 5 is a diagram illustrating how level values and the respective run values may be stored in a coefficient information storage unit of FIG. 2;

FIG. 6 is a diagram illustrating the operation of an internal total coefficient number storage of FIG. 4, which may be used for generating a total coefficient number of a current block;

FIG. 7 is a flowchart illustrating operations associated with generating coefficient information, which may be used in a context-adaptive VLC method according to some embodiments of the present invention;

FIG. 8 is a flowchart illustrating the calculation of a trailing ones number of a current block, which may be used in a context-adaptive VLC method according to some embodiments of the present invention;

FIG. 9 is a flowchart illustrating the generation of a total coefficient number of a current block, which may be used in a context-adaptive VLC method according to some embodiments of the present invention; and

FIG. 10 is a flowchart illustrating the generation of bit data, which may be used in a context-adaptive VLC method according to some embodiments of the present invention.

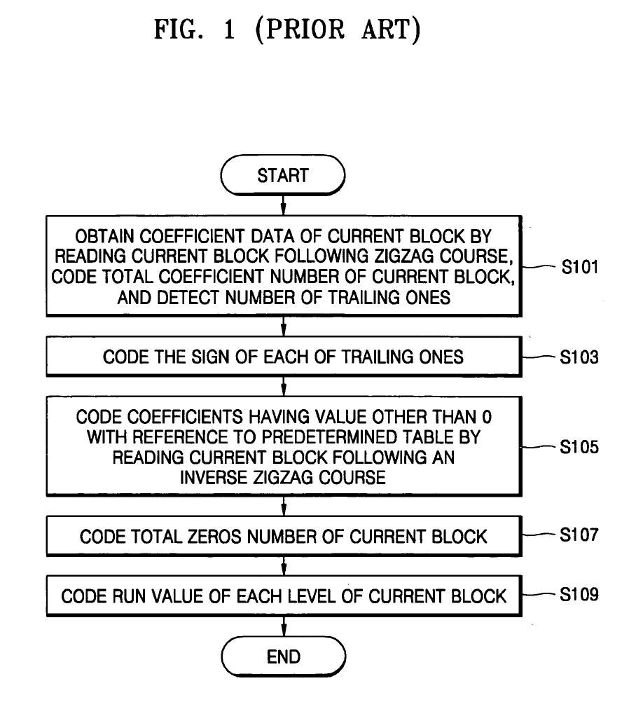

### DETAILED DESCRIPTION OF EMBODIMENTS OF THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

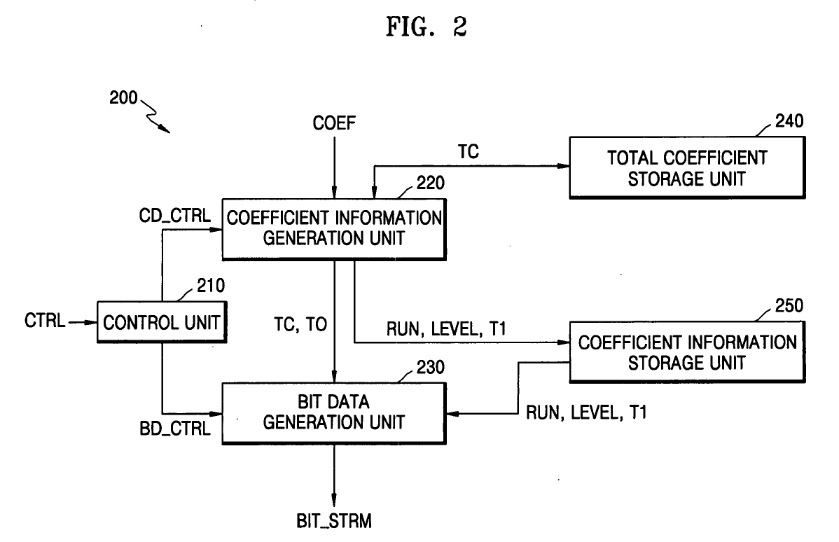

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein. FIG. 2 is a block diagram of a context-adaptive variable length coding (VLC) apparatus 200 according to an exemplary embodiment of the present invention. Referring to FIG. 2, the context-adaptive VLC apparatus 200 includes a control unit 210, a coefficient information generation unit 220, and a bit data generation unit 230. The context-adaptive VLC apparatus 200 may also include a total coefficient number storage unit 240 and a coefficient information storage unit 250.

The coefficient information generation unit 220 operates in response to an information generation control signal CD_CTRL. The coefficient information generation unit 220 generates coefficient information used for coding coefficients COEF of a current block of a current macroblock based on the coefficients COEF read out from the current block following an inverse zigzag course. The coefficient information includes a total coefficient number TC, a trailing ones number T1, run values RUN, level values LEVEL, and a total zeros number T0.

The bit data generation unit 230 operates in response to a bit generation control signal BD_CTRL. The bit data generation unit 230 codes coefficients of a previous block of the current macroblock based on coefficient information of the previous block and then outputs a coded bitstream BIT_STRM as the coding result.

While the coefficient information generation unit 220 reads the coefficients of the current block and generates the coefficient information of the current block, the bit data generation unit 230 codes the coefficients of the previous block based on the coefficient information of the previous block. In other words, the coefficient information generation unit 220 and the bit data generation unit 230 may operate in parallel at the same time.

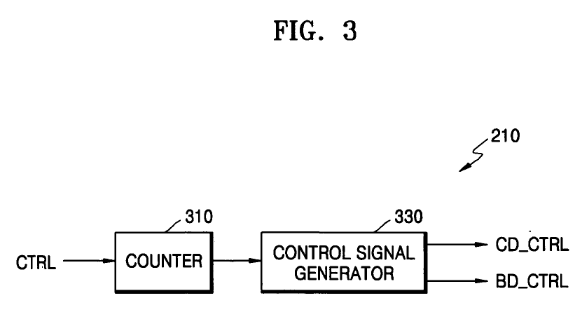

The control unit 210 generates the information generation control signal CD_CTRL used for controlling the operation of the coefficient information generation unit 220 and the bit data generation control signal BD_CTRL used for controlling the operation of the bit data generation unit 230 in response to a predetermined control signal CTRL. The operation of the control unit 210 will now be described in further detail with reference to FIG. 3.

FIG. 3 is a block diagram of the control unit 210 of FIG. 2. Referring to FIG. 3, the control unit 210 includes a counter 310, which counts up to a value of (N+1) (where N is a total number of blocks of the current macroblock), and a control signal generator 330. The counter 310 is reset in response to the control signal CTRL, which is used for commanding the context-adaptive variable length coding apparatus 200 to code the current macroblock, and which periodically counts the block number of the current macroblock.

The counting period of the counter 310 may be provided so that all of the following operations can be done within one counting period: reading all of the coefficients of the current block, generating the coefficient information of the current block, and coding all of the coefficients of the previous block based on the coefficient information of the previous block.

The control signal generator 330 generates the information generation control signal CD_CTRL and the bit generation control signal BD_CTRL based on the output of the counter 310.

Specifically, the control signal generator 330 may generate only the information generation control signal CD_CTRL in a first count so that the coefficient information generation unit 220 generates coefficient information for a first block of the current macroblock in response to the information generation control signal CD_CTRL.

Thereafter, the control signal generator 330 may generate both the information generation control signal CD_CTRL and the bit generation control signal BD_CTRL in a subsequent count. For example, in a second count, the control signal generator 330 may cause the coefficient information generation unit 220 to generate coefficient information of a second block of the current macroblock and may at the same time cause the bit data generation unit 230 to code the first block of the current macroblock based on the coefficient information generated for the first block by the coefficient information generation unit 220.

The control signal generation unit 330 generates both the information generation control signal CD_CTRL and the bit generation control signal BD_CTRL in each of second through N-th counts.

In short, the control signal generator 330 is configured to cause the coefficient information generation unit 220 to generate coefficient information for the current block while also causing the bit data generation unit 230 to code the coefficients of the previous block based on the coefficient information previously generated for the previous block by the coefficient information generation unit 220.

In an (N+1)-th count, the control signal generator 330 may generate only the bit generation control signal BD_CTRL and thus may cause the bit generation unit 230 to code an N-th block of the current macroblock in response to the bit generation control signal BD_CTRL based on coefficient information of the N-th block.

Referring again to FIG. 2, the total coefficient number storage unit 240 stores coefficients obtained from a previous macroblock. The coefficients stored in the total coefficient number storage unit 240 are described in detail below.

The coefficient information storage unit 250 stores coefficient information generated by the coefficient information generation unit 220. The coefficient information may include, for example, the level values LEVEL, the run values RUN, and/or the trailing ones number T1.

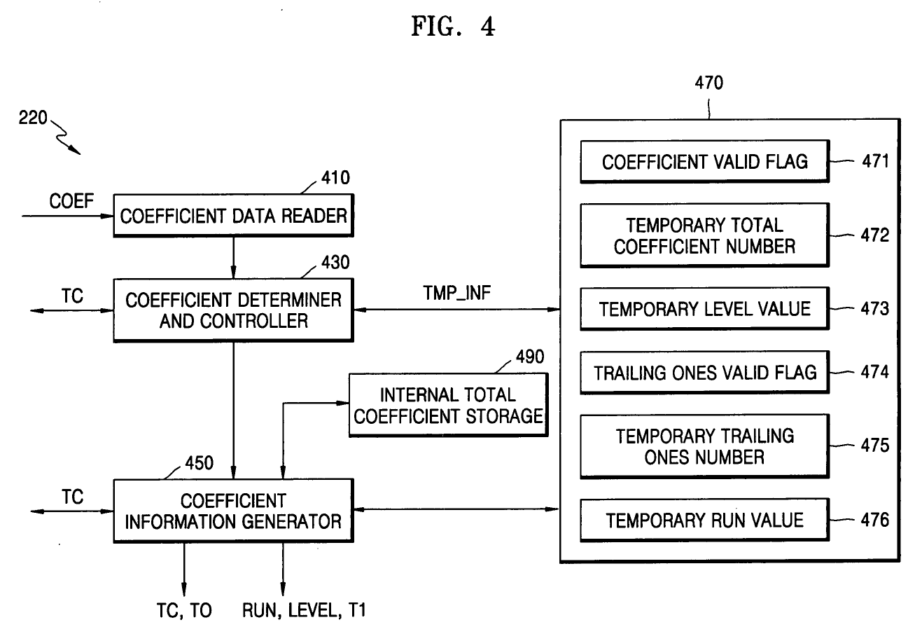

The operation of the coefficient information generation unit 220 will now be described in further detail with reference to FIG. 4.

FIG. 4 is a block diagram of the coefficient information generation unit 220 of FIG. 2. Referring to FIG. 4, the coefficient information generation unit 220 includes a coefficient data reader 410, a coefficient determiner and controller 430, a coefficient information generator 450, a temporary storage 470, and an internal total coefficient number storage 490.

The coefficient reader 410 sequentially reads the coefficients COEF of the current block following an inverse zigzag course, and then sequentially transmits the coefficients to the coefficient determiner and controller 430.

In some embodiments, unlike in the prior art, the current block is read only one time following an inverse zigzag course, which may reduce the time required for coding the coefficients of the current block.

The coefficient determiner and controller 430 generates temporary information TMP_INF, which may be used for generating coefficient information for each of the coefficients sequentially transmitted by the coefficient reader 410, and transmits the temporary information TMP_INF to the temporary storage 470.

The temporary information TMP_INF includes a coefficient valid flag 471, a temporary total coefficient number 472, a temporary level value 473, a trailing ones valid flag 474, a temporary trailing ones number 475, and a temporary run value 476.

The coefficient valid flag 471 indicates whether a coefficient having a value other than 0 has been read out from the current block. Specifically, when a coefficient having a value other than 0 is read out for the first time from the current block, the coefficient valid flag 471 is set. Thereafter, when the reading of all of the coefficients of the current block is complete, the coefficient valid flag 471 is reset.

The temporary total coefficient number 472 is an accumulated number of coefficients having a value of 0 that have been read out from the current block. When the reading of all of the coefficients of the current block is complete, the temporary total coefficient number 472 is set as the total coefficient number TC.

The temporary level value 473 is the value of a coefficient having a value other than 0 that has been most recently read out from the current block and is updated and stored whenever a coefficient having a value other than 0 is read out from the current block.

The trailing ones valid flag 474 indicates whether consecutive coefficients having an absolute value of 1 have been read out for the first time from the current block. In other words, when a coefficient read out from the current block is the first coefficient ever read out from the current block having an absolute value of 1, the trailing ones valid flag 474 is set. Thereafter, if a coefficient subsequent to the coefficient having a value of 1 also has an absolute value of 1, the trailing ones valid flag 474 is maintained. However, if the subsequent coefficient does not have an absolute value of 1, the trailing ones valid flag 474 is reset.

The temporary trailing ones number 475 is an accumulated number of consecutive coefficients having an absolute value of 1 that have been read out for the first time from the current block. When the reading of all of the coefficients of the current block is complete, the temporary trailing ones number 475 is set as the trailing ones number T1. In some embodiments, the trailing ones number T1 may not exceed 3.

The temporary run value 476 is an accumulated number of consecutive coefficients having a value of 0 between a pair of coefficients having a value other than 0 (i.e., between a pair of levels) that have been most recently read out from the current block. Accordingly, the temporary run value 476 is updated together with the temporary level value 473. A method of updating the run value RUN along with the level value LEVEL will be described in detail below.

The coefficient information generator 450 generates coefficient information based on the temporary information TMP_INF.

Methods of generating the temporary information TMP_INF by reading the coefficients from the current block and then generating coefficient information based on the temporary information TMP_INF will now be described in detail with reference to FIG. 2 and FIG. 4.

Referring to FIG. 2, the coefficient information generation unit 220 begins its operation in response to the information generation control signal CD_CTRL in order to generate coefficient information for each of the coefficients read out from the current block. Referring to FIG. 4, the coefficient reader 410 sequentially reads the coefficients of the current block by reading the current block following an inverse zigzag course and sequentially transmits the coefficients to the coefficient determiner and controller 430.

The coefficient determiner and controller 430 determines whether each of the coefficients transmitted by the coefficient reader 410 has a value of 0. If a current coefficient transmitted by the coefficient reader 410 has a value of 0, the coefficient determiner and controller 430 increases the temporary run value 476 by 1 and determines whether a coefficient subsequent to the current coefficient has a value of 0. However, if the current coefficient does not have a value of 0, the coefficient determiner and controller 430 increases the temporary total coefficient number 472 by 1 and then determines whether the current coefficient has an absolute value of 1. If the current coefficient has an absolute value of 1, an operation of calculating the trailing ones number T1 and then an operation of calculating the run value RUN and the level value LEVEL are carried out. The operation of calculating the trailing ones number T1 will now be described in detail.

If the current coefficient has an absolute value of 1, the coefficient determiner and controller 430 determines whether a coefficient having an absolute value of 1 was transmitted before the current coefficient. If a coefficient having an absolute value of 1 was not transmitted ahead of the current coefficient, the current coefficient is considered to be the first coefficient ever transmitted having an absolute value of 1. Thus, the trailing ones valid flag 474 is set, and the temporary trailing ones number 475 is increased by 1.

If a coefficient having an absolute value of 1 had already been transmitted ahead of the current coefficient, the coefficient determiner and controller 430 determines whether a coefficient previous to the current coefficient also had an absolute value of 1. If the previous coefficient does not have an absolute value of 1, it is determined that there is no need to count trailing ones. Thus, the trailing ones valid flag 474 is reset, and the temporary trailing ones number 475 is maintained.

If the previous coefficient also has an absolute value of 1, the coefficient determiner and controller 430 determines whether a coefficient previous to the previous coefficient also has an absolute value of 1. Thereafter, the coefficient determiner and controller 430 determines whether the trailing ones valid flag 474 is currently set. If the trailing ones valid flag 474 is not yet set, the temporary trailing ones number 475 is maintained. Even though the trailing ones valid flag 474 is set, the trailing ones number T1 cannot exceed 3. Thus, if the trailing ones valid flag 474 is set, the coefficient determiner and controller 430 determines whether the temporary trailing ones number 475 is smaller than 3. If the temporary trailing ones number 475 is smaller than 3, the coefficient determiner and controller 430 increases the temporary trailing ones number 475 by 1. However, if the temporary trailing ones number 475 is not smaller than 3, the coefficient determiner and controller 430 maintains the temporary trailing ones number 475.

Referring still to FIG. 4, if the current coefficient does not have an absolute value of 1, the trailing ones valid flag 474 is reset. Thereafter, it is determined whether coefficients having a value other than 0 had already been transmitted ahead of the current coefficient. Thereafter, it is determined whether to carry out the operation of calculating the run value RUN and the level value LEVEL based on the determination results.

The operation of calculating the run value RUN and the level value LEVEL will now be described in detail.

If coefficients having a value other than 0 had not yet been transmitted ahead of the current coefficient, the current coefficient is considered to be the first coefficient ever transmitted having a value other than 0, in which case, the temporary level value 473 is yet to be calculated, and the temporary run value 476 is invalid.

Accordingly, the temporary level value 473 is calculated based on the current coefficient, and the temporary run value 476 is reset. In addition, the coefficient valid flag 471 is set.

If the coefficient valid flag 471 is set, it appears that a coefficient having a value other than 0 has already been transmitted. If the coefficient valid flag 471 is reset, it appears that a coefficient having a value other than 0 has not yet been transmitted.

If a coefficient having a value other than 0 has already been transmitted, the temporary level 473 is equal to the number of coefficients having a value other than 0 transmitted before the current coefficient, and the temporary run value 476 is equal to an accumulated number of coefficients having a value of 0 between a pair of coefficients having a value other than 0.

Accordingly, the coefficient information generator 450 stores the temporary level value 473 and the temporary run value 476 in the coefficient information storage unit 250 as the level value LEVEL and the run value RUN, respectively.

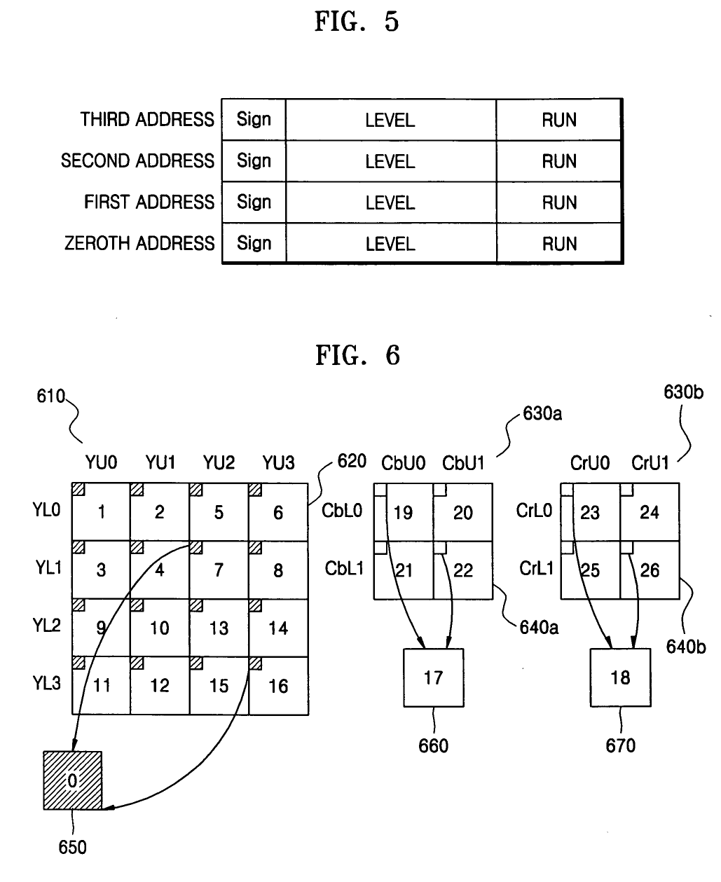

FIG. 5 is a diagram illustrating how run values and the respective level values are stored in the coefficient information storage unit 250. Referring to FIG. 5, the values and signs of levels and run values respectively corresponding to the levels are stored in of the coefficient information storage unit 250 in such a manner that addresses are sequentially taken from the zeroth address. Since the total coefficient number TC is a total number of coefficients having a value other than 0, it can be obtained based on the number of addresses where the level values are stored.

Referring again to FIG. 4, after storing the temporary level value 473 and the temporary run value 476 in the coefficient information storage unit 250, the coefficient determiner and controller 430 updates the temporary level value 473 and resets the temporary run value 476 based on the values of the coefficients transmitted thereto.

Thereafter, the coefficient determiner and controller 430 determines whether all of the coefficients of the current block have been transmitted thereto. If not all of the coefficients of the current block have been transmitted to the coefficient determiner and controller 430, the coefficient determiner and controller 430 continues to determine whether each of the coefficients of the current block transmitted afterwards has a value of 0.

If all of the coefficients of the current block have been transmitted to the coefficient determiner and controller 430, the coefficient information generator 450 generates coefficient information based on the temporary information TMP_INF stored in the temporary storage 470.

Specifically, the coefficient information generator 450 stores the temporary level value 473, the temporary run value 476, and the temporary trailing ones number 475 in the coefficient information storage unit 250 as the level value LEVEL, the run value RUN, and the trailing ones number T1, respectively.

In addition, the coefficient information generator 450 stores the temporary total coefficient number 472 in the internal total coefficient number storage 490 as the total coefficient number TC and transmits it to the bit data generation unit 230 along with other total coefficient numbers previously stored in the internal total coefficient number storage 490. The coefficient information generator 450 subtracts the total coefficient number TC (which represents the number of non-zero coefficients in the current block) from the total number of coefficients of the current block to determine a total zeros number T0, and transmits the total zeros number T0 to the bit data generation unit 230.

The operation of the coefficient information generator 450 will now be described in further detail with reference to FIG. 6.

FIG. 6 is a diagram illustrating the internal total coefficient number storage 490, which is used for calculating the total coefficient number TC. Specifically, FIG. 6 illustrates one macroblock 610 including a plurality of blocks 620.

Referring to FIG. 6, one macroblock 610 is comprised of 16 blocks 620, i.e., first through sixteenth luminance blocks 620, which are obtained by varying the luminance of image data, and two groups 630a, 630b of four blocks each, i.e., nineteenth through twenty second chrominance blocks 640a and twenty third through twenty sixth chrominance blocks 640b, which are obtained by varying the chrominance of the image data.

In a coding mode where DC coefficients of a macroblock are coded separately from other coefficients, the macroblock may also include a zeroth block 650, which includes DC coefficients of the first through sixteenth luminance blocks 620, a seventeenth block, which is comprised of DC coefficients of the nineteenth through twenty second chrominance blocks 640a, and an eighteenth block 670, which includes DC coefficients of the twenty third through twenty sixth chrominance blocks 640b.

The bit data generation unit 230 uses the total coefficient numbers of blocks adjacent to the current block, for example, blocks at the left and upper sides of the current block, for coding the coefficients of the current block.

Accordingly, if all of the coefficients of the current block have been transmitted, the coefficient information generator 450 transmits the coefficients of each of the blocks adjacent to the current block as well as all of the coefficients of the current block to the bit data generation unit 230.

For example, if the seventh block is the current block, the coefficient information generator 450 transmits the coefficients of each of the fourth and fifth blocks as well as the coefficients of the seventh block to the bit data generation unit 230.

Accordingly, the coefficient information generator 450 stores all of the coefficients of each of the blocks of the current macroblock in the internal total coefficient number storage 490 in a predetermined order so that all of the coefficients of each of the blocks adjacent to the current block can be transmitted to the bit data generation unit 230 along with all of the coefficients of the current block.

Referring to FIG. 6, whenever the total coefficient numbers of each block are determined, they are stored in the respective left buffers YL0 through YL3, CbL0, CbL1, CrL0, and CrL1 and in the respective upper buffers YU0 through YU3, CbU0, CbU1, CrU0, and CrU1. Accordingly, the total coefficient numbers of each of the blocks adjacent to the current block can be transmitted. The internal total coefficient number storage 490 includes such left and upper buffers which update and store total coefficient numbers of the blocks of the current macroblock.

For example, if a total coefficient number of the fifth block is determined, it is stored in the left buffer YL0 and the upper buffer YU2. Likewise, if a total coefficient number of the sixth block is determined, it is stored in the left buffer YL0 and the upper buffer YU3. As a result of determining the total coefficient numbers of the third through sixth blocks, the total coefficient number of the sixth block and the total coefficient number of the fourth block are stored in the left buffers YL0 and YL1, respectively, and a total coefficient number of the third block, the total coefficient number of the fourth block, the total coefficient number of the fifth block, and the total coefficient number of the sixth block are stored in the upper buffers YU0, YU1, YU2, and YU3, respectively.

Accordingly, if the total coefficient number of the current block has been determined, the coefficient information generator 450 reads the total coefficient numbers of the blocks adjacent to the current block from left and upper buffers of the internal total coefficient number storage 490 where the determined total coefficient number of the current block is to be stored and transmits the read total coefficient numbers to the bit data generation unit 230 together with the determined total coefficient number of the current block. Thereafter, the coefficient information generator 450 stores the determined total coefficient number of the current block in the left and upper buffers.

For example, if a total coefficient number of the thirteenth block has been determined, the coefficient information generator 450 transmits total coefficient numbers previously stored in the left buffer YL2 and the upper buffer YU2 corresponding to the thirteenth block to the bit data generation unit 230. Thereafter, the coefficient information generator 450 stores the determined total coefficient number of the thirteenth block in the left buffer YL2 and the upper buffer YU2.

When the coding of all of the blocks of the current macroblock is complete, a macroblock at the right side of the current macroblock is coded. The total coefficient numbers stored in the left buffers YL0 through YL3, CbL0, CbL1, CrL0, and CrL1 can be used for coding the macroblock at the right side of the current macroblock, while the total coefficient numbers stored in the upper buffers YU0 through YU3, CbU0, CbU1, CrU0, and CrU1 cannot be used for coding the macroblock at the right side of the current macroblock.

Since the total coefficient numbers stored in the upper buffers YU0 through YU3, CbU0, CbU1, CrU0, and CrU1 can be used for coding the macroblock below the current block, they are also stored in the total coefficient number storage unit 240 of FIG. 2.

In other words, when the coding of all of the blocks of the current macroblock is complete, the coefficient information generator 450 stores the total coefficient numbers previously stored in the upper buffers of the internal total coefficient number storage 490 in the total coefficient number storage unit 240. The total coefficient numbers stored in the upper buffers of the internal total coefficient storage 490 may be the total coefficient numbers of the eleventh, twelfth, fifteenth, sixteenth, twenty first, twenty second, twenty fifth, and twenty sixth blocks.

The coefficient information generator 450 reads the total coefficient numbers of eleventh, twelfth, fifteenth, sixteenth, twenty first, twenty second, twenty fifth, and twenty sixth blocks of a upper macroblock from the total coefficient storage unit 240 and then stores them in the respective upper blocks of the current macroblock.

The bit data generation unit 230 converts the coefficients of the current block into bit data based on a predetermined table selected in response to the coefficient information generated by the coefficient information generation unit 220.

The bit data generation unit 230 selects one of the total coefficient tables with reference to predetermined total coefficient numbers, and particularly, with reference to the total coefficient numbers of the blocks at the left and upper sides of the current block and then codes all of the coefficients of the previous block with reference to the selected total coefficient table.

In addition, the bit data generation unit 230 selects one of a plurality of level tables based on a plurality of level values stored in the coefficient information storage unit 250 and codes the level values of the previous block with reference to the selected level table. The bit data generation unit 230 does not code levels having an absolute value of 1.

Thereafter, the bit data generation unit 230 selects one of a plurality of total zeros tables with reference to the total coefficient number TC of the previous block and codes the total zeros number T0 of the previous block with reference to the selected total zeros table. Thereafter, the bit data generation unit 230 codes the run value RUN of the previous block stored in the coefficient information storage unit 250.

Thereafter, the bit data generation unit 230 outputs the coding results as a bitstream.

A context-adaptive VLC method according to an exemplary embodiment of the present invention will now be described.

In the context-adaptive VLC method according to an exemplary embodiment of the present invention, an operation of generating coefficient information of a current block and an operation of coding all of a plurality of coefficients of a previous block are performed in parallel.

In other words, coefficient information used for coding the current block is generated by reading coefficients from the current block following an inverse zigzag course, and simultaneously, coefficients of a previous block are coded with reference to a predetermined coding table, which is selected with reference to coefficient information of the previous block.

The coefficient information of the current or previous block may include a total coefficient number, a trailing ones number, a level value, a run value, and a total zeros number.

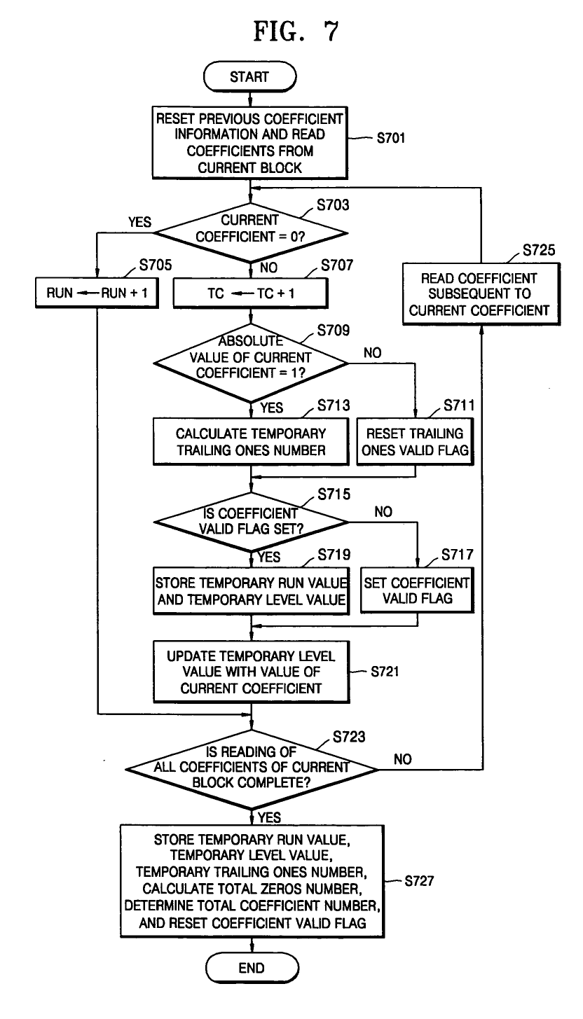

The context-adaptive VLC method according to an exemplary embodiment of the present invention will now be described with reference to FIGS. 7 through 10.

FIG. 7 is a flowchart of a method of generating coefficient information of a block, which is used in the context-adaptive VLC method according to an exemplary embodiment of the present invention. Referring to FIG. 7, in operation S701, all previous coefficient information is reset, and coefficients are read out from a current block. Specifically, the coefficients are read out from the current block by reading the current block following an inverse zigzag course and then are sequentially used for generating coefficient information of the current block. In some embodiments, the coefficients are read out from the current block only once.

In operation S703, it is determined whether a current coefficient of the current block has a value of 0 in order to calculate a temporary run value or a temporary total coefficient number. In operation S705, if the current coefficient has a value of 0, the temporary run value is increased by 1. In operation S707, if the current coefficient has a value other than 0, the temporary total coefficient number is increased by 1. In operation S709, it is determined whether the current coefficient has an absolute value of 1 in order to calculate a temporary trailing ones number.

In operation S711, if the current coefficient has an absolute value other than 1, a trailing ones valid flag is reset. Before operation S711, the trailing ones valid flag may have already been set or reset. Therefore, if the trailing ones valid flag was set before operation S711, the trailing ones valid flag is reset in operation S711. If the trailing ones valid flag was reset before operation S711, the trailing ones valid flag is maintained to be reset in operation S711.

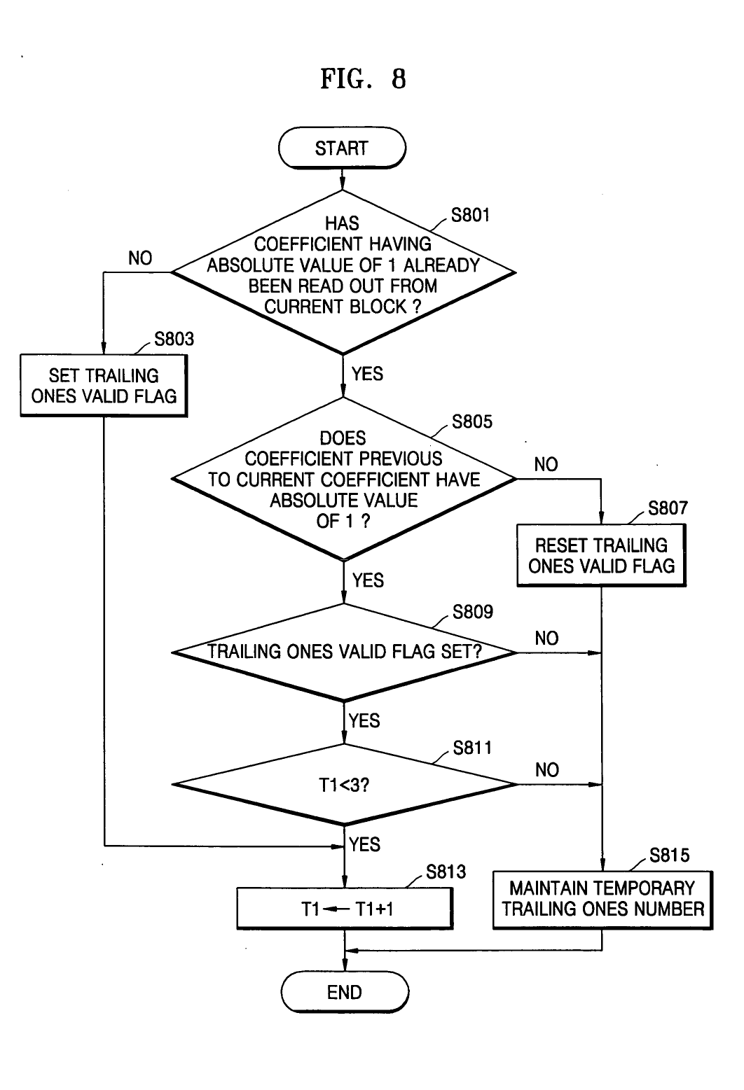

In operation S713, if the current coefficient has an absolute value of 1, a temporary trailing ones number is calculated. A method of calculating a trailing ones number of a current block will be described in detail later with reference to FIG. 8.

In operation S715, it is determined whether a coefficient valid flag is set. When set, the coefficient valid flag indicates that a coefficient having a value other than 0 has already been read out from the current block. When reset, the coefficient valid flag indicates that a coefficient having a value other than 0 has not yet been read out from the current block.

All previous coefficient information is reset when the operation of generating coefficient information of the current block begins. If a coefficient having a value other than 0 has been read out from the current block, the coefficient valid flag will be set. However, if a coefficient having a value other than 0 has not yet been read out from the current block, the coefficient valid flag remains reset.

Accordingly, if the coefficient valid flag is not yet to be set, then it is set in operation S717, a temporary level value is updated with the value of the current coefficient, and the updating result is stored, and the temporary run value is reset in operation S721.

However, if the coefficient valid flag is already set, then the temporary level value and the temporary run value are stored in operation S719, the temporary level value is updated with the value of the current coefficient, the update result is stored, and the temporary run value is reset in operation S721.

In operation S723, it is determined whether the reading of all of the coefficients of the current block is complete. If the reading of all of the coefficients of the current block is yet to be complete, a coefficient subsequent to the current coefficient is read in operation S725, and then operations S703 through 723 are repeated.

In operation S727, if the reading of all of the coefficients of the current block is complete, the temporary total coefficient number, the temporary trailing ones number, the temporary level value, and the temporary run value are stored as a total coefficient number, a trailing ones number, a level value, and a run value of the current block, a total zeros number is calculated by obtaining a difference between the total number of coefficients of the current block and the total coefficient number of the current block, and the coefficient valid flag is reset.

FIG. 8 is a flowchart of a method of calculating a trailing ones number, which is used in the context-adaptive VLC method according to an exemplary embodiment of the present invention. Referring to FIG. 8, in operation S801, if the current coefficient has an absolute value of 1, it is determined whether a coefficient having an absolute value of 1 had already been read out from a current block before a current coefficient. If a coefficient having an absolute value of 1 had not yet been read out from the current block before the current coefficient, the trailing ones valid flag is set in operation S803, and a trailing ones number is increased by 1 in operation S813 because it appears that the current coefficient is the first coefficient ever read out from the current block having an absolute value of 1.

However, in operation S805, if a coefficient having an absolute value of 1 had already been read out from the current block, it is determined whether a coefficient previous to the current coefficient has an absolute value of 1 in order to decide whether to increase the trailing ones number by 1.

If the previous coefficient does not have an absolute value of 1, it appears that the previous coefficient is not a trailing one. Thus, a trailing valid flag is reset in operation S807, and the trailing ones number is maintained in operation S815.

In operation S809, if the previous coefficient has an absolute value of 1, it is determined whether the trailing ones valid flag is set in order to determine whether the previous coefficient is the first coefficient ever read out from the current block having an absolute value of 1. In operation S815, the trailing ones number is maintained because, when not set, the trailing ones valid flag indicates that the previous coefficient is not the first coefficient ever read out from the current block having an absolute value of 1.

When set, the trailing ones valid flag indicates that the previous coefficient is the first coefficient ever read out from the current block having an absolute value of 1, in which case, the trailing ones number can be increased by 1. In operation S811, it is determined whether the trailing ones number is smaller than 3 because the trailing ones number is not allowed to exceed 3.

In operation S813, if the trailing ones number is smaller than 3, it is increased by 1. However, if the trailing ones number is not smaller than 3, it is maintained.

In order to code the coefficients of the current block, all of a plurality of coefficients of blocks adjacent to the current block, i.e., blocks at the left and upper sides of the current block, are used.

For example, as shown in FIG. 6, the lowermost blocks of a macroblock at the upper side of a previous macroblock, i.e., eleventh, twelfth, fifteenth, sixteenth, twenty first, twenty second, twenty fifth, and twenty sixth blocks, are used for coding the uppermost blocks of the current macroblock, i.e., first, second, fifth, sixth, nineteenth, twentieth, twenty third, and twenty fourth blocks.

Accordingly, the total coefficient number of the current block needs to be stored in a predetermined internal memory so that a total coefficient number previously stored in the internal memory can be updated with the total coefficient number of the current block. In addition, the total coefficient numbers of the lowermost blocks of the upper macroblock may be stored in a memory separate from the internal memory.

In the present embodiment, the internal total coefficient storage 490 of FIG. 4 is used as the internal memory, and the total coefficient numbers of the lowermost blocks of the upper macroblock are stored in the total coefficient storage unit 240. However, the present invention is not restricted to the embodiment set forth herein.

The internal memory includes left buffers and upper buffers, which store total coefficient numbers of a plurality of blocks of each macroblock.

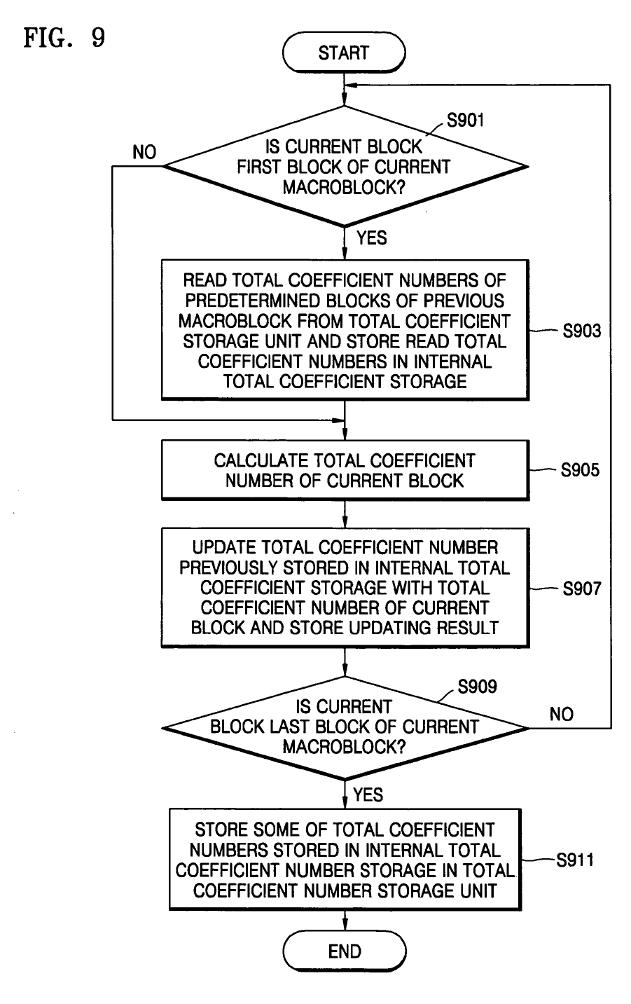

FIG. 9 is a flowchart of a method of storing a total coefficient number of a current block, which is used in the context-adaptive VLC method according to an exemplary embodiment of the present invention. Referring to FIG. 9, in operation S901, it is determined whether a current block is a first block of a current macroblock. If the current block is not the first block of the current macroblock, the method proceeds to operation S905. In operation S903, if the current block is the first block of the current macroblock, the total coefficient numbers of lowermost blocks of a macroblock at the upper side of the current macroblock are read and then stored in the upper buffers of an internal memory. In operation S905, a total coefficient number of the current block is calculated.

In operation S907, the total coefficient number of the current block is stored in the internal memory, and particularly, in a corresponding left buffer and a corresponding upper buffer of the internal memory, so that a total coefficient number previously stored in the corresponding left and upper buffers of the internal memory can be replaced with the total coefficient number of the current block. In operation S909, it is determined whether the current block is the last block of the current macroblock.

If the current block is not the last block of the current macroblock, operations S901 through S907 are repeated. However, if the current block is the last block of the current macroblock, some of the total coefficient numbers stored in the internal memory, and particularly, the total coefficient numbers stored in upper buffers of the internal memory are stored in a total coefficient storage unit in operation S911.

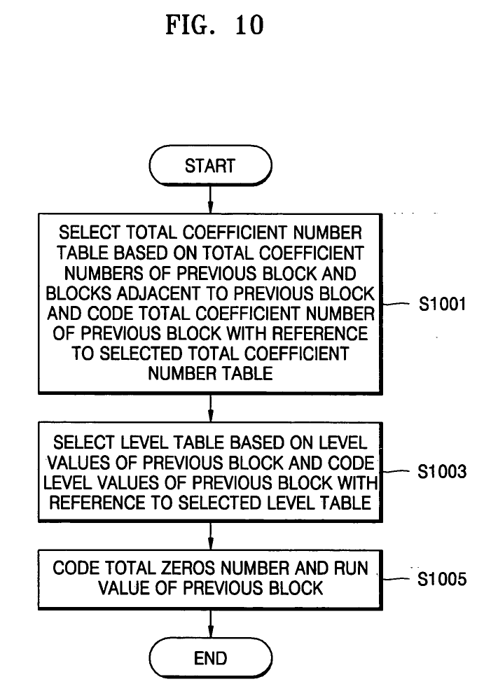

FIG. 10 is a flowchart illustrating the generation of bit data, which is used in the context-adaptive VLC method according to an exemplary embodiment of the present invention. Referring to FIG. 10, a plurality of coefficients of a previous block are sequentially coded with reference to a group of tables selected based on the coefficient information of the previous block.

Specifically, in operation S1001, a total coefficient table is selected with reference to total coefficient numbers of the previous block and blocks adjacent to the previous block (e.g., blocks at the left and upper side of the previous block), and the total coefficient number of the previous block is coded with reference to the selected total coefficient table.

In operation S1003, level values of the previous block are coded with reference to a level table selected based on the level values of the previous block. Of the level values of the previous block, those having an absolute value of 1 are not coded in operation S1003.

Thereafter, a total zeros number of the previous block is coded with reference to a table selected based on the total coefficient number of the previous block, and then run values of the previous block are coded.

As described above, the context-adaptive VLC apparatus and method according to the present invention can generate coefficient information used for coding image data based on coefficients by reading coefficients only once from the image data using statistical information.

In addition, the context-adaptive VLC apparatus and method according to the present invention can reduce the time required for coding image data and thus can quickly code the image data by performing in parallel an operation of generating coefficient information used for coding the image data and an operation of generating bit data based on the coefficient information.

As will be appreciated by one of skill in the art, the present invention may be embodied as a method, data processing system, and/or computer program product. Accordingly, the present invention may take the form of an entirely hardware embodiment, an entirely software embodiment or an embodiment combining software and hardware aspects all generally referred to herein as a “circuit” or “module.” Furthermore, the present invention may take the form of a computer program product on a computer usable storage medium having computer usable program code embodied in the medium. Any suitable computer readable medium may be utilized including hard disks, CD ROMs, optical storage devices, a transmission media such as those supporting the Internet or an intranet, or magnetic storage devices.

The present invention is described below with reference to flowchart illustrations and/or block diagrams of methods, systems and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable memory that can direct a computer or other programmable data processing apparatus to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

Computer program code for carrying out operations of the present invention may be written in an object oriented programming language such as Java®, Smalltalk or C++. However, the computer program code for carrying out operations of the present invention may also be written in conventional procedural programming languages, such as the “C” programming language. The program code may execute entirely on the user's computer, partly on the user's computer, as a stand alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

While the present invention has been particularly shown and described with reference to exemplary embodiments thereof, it will be understood by those of ordinary skill in the art that various changes in form and details may be made therein without departing from the spirit and scope of the present invention, which is set forth in the following claims.

What is claimed is:

1. A context-adaptive variable length coding (VLC) apparatus, comprising:
a coefficient information generation unit configured to generate coefficient information used for coding variable-length-code coefficients for a selected block of a selected macroblock of image data that is read out in response to an information generation control signal;
a bit data generation unit configured to operate in response to a bit generation control signal, and to code coefficients of a previous block, which is read out just before the selected block, using coefficient information of the previous block; and
a control unit configured to generate the information generation control signal and the bit generation control signal, and to cause the coefficient information generation unit and the bit data generation unit to operate in parallel using the information generation control signal and the bit generation control signal.

2. The context-adaptive VLC apparatus of claim 1, further comprising:
a total coefficient number storage unit configured to store total coefficient numbers of all blocks of the selected macroblock and of a macroblock at the upper side of the selected macroblock; and
a coefficient information storage unit configured to store part of the coefficient information of the selected block,
wherein the coefficient information stored in the coefficient information storage unit comprises a trailing ones number, a level value, and/or a run value.

3. The context-adaptive VLC apparatus of claim 1, wherein the control unit comprises:
a counter, which counts up to (N+1) where N is a total number of blocks in the selected macroblock; and
a control signal generator, which generates the information generation control signal and the bit generation control signal in response to an output of the counter.

4. The context-adaptive VLC apparatus of claim 3, wherein the control signal generator generates only the information generation control signal in a first count, generates both the information generation control signal and the bit generation control signal in each of second through N-th counts, and generates only the bit generation control signal in an (N+1)-th count.

5. The context-adaptive VLC apparatus of claim 1, wherein the coefficient information generation unit comprises:
a coefficient data reader configured to read the coefficients of the selected block only once following an inverse zigzag course;
a coefficient determiner and controller configured to generate-temporary coefficient information used for generating the coefficient information of the selected block based on the coefficients of the selected block and the previous block;
a temporary information storage configured to store the temporary coefficient information generated by the coefficient determiner and controller; and
a coefficient information generator configured to generate the coefficient information of the selected block based on the temporary information stored in the temporary information storage.

6. The context-adaptive VLC apparatus of claim 5, wherein the temporary information storage stores a coefficient valid flag, which indicates whether a coefficient having a value other than 0 has been read out from the selected block, a temporary total coefficient number, which is an accumulated number of coefficients having a value of other than 0 that have been read out from the selected block, a temporary level value, which is the value of a coefficient having a value other than 0 that has been most recently read out from the selected block, a trailing ones valid flag, which indicates whether consecutive coefficients having an absolute value of 1 have been read out for the first time from the selected block, a temporary trailing ones number, which is an accumulated number of consecutive coefficients having an absolute value of 1 that have been read out for the first time from the selected block, and a temporary run value, which is an accumulated number of consecutive coefficients having a value of 0 between a pair of coefficients having a value other than 0 that have been most recently read out from the selected block.

7. The context-adaptive VLC apparatus of claim 6, wherein the coefficient determiner and controller is configured to determine whether to set or reset the coefficient valid flag and the temporary trailing ones valid flag, whether to increase the temporary total coefficient number, the temporary trailing ones number, and the temporary run value, and whether to update the temporary level value based on each of the coefficients of the selected block read by the coefficient reader.

8. The context-adaptive VLC apparatus of claim 7, wherein the coefficient information generator is configured to increase the temporary run value if a selected coefficient currently being read out from the selected block has a value of 0 and to reset the temporary run value if the selected coefficient does not have a value of 0; and
wherein the coefficient information generator is further configured to store the temporary level value and the temporary run value in the coefficient information storage unit as the level value and the run value, respectively, and to update the temporary level value with the value of the selected coefficient.

9. The context-adaptive VLC apparatus of claim 8, wherein the coefficient determiner and controller is configured to increase the temporary trailing ones number in response to the trailing ones valid flag if the selected coefficient has an absolute value of 1 and the temporary trailing ones number is less than three.

10. The context-adaptive VLC apparatus of claim 7, wherein the coefficient determiner and controller is configured to store the trailing ones number, the level value, and the run value in the coefficient information storage unit based on the temporary coefficient information when the reading of all of the coefficients of the selected block is complete, and is further configured to transmit a group of total coefficient numbers and a total zeros number of the selected block to the bit data generation unit.

11. The context-adaptive VLC apparatus of claim 10, wherein the coefficient information generator is configured to store the temporary trailing ones number, the temporary run value, and the temporary level value in the coefficient information storage unit as the trailing ones number, the level value, and the run value, respectively.

12. The context-adaptive VLC apparatus of claim 10, wherein the coefficient determiner and controller is configured to determine the total zeros number of the selected block by subtracting the total coefficient number of the selected block from a total number of coefficients of the selected block.

13. The context-adaptive VLC apparatus of claim 10, wherein the group of total coefficient numbers comprises the total coefficient number of the selected block and total coefficient numbers of blocks at the left and upper sides of the selected block.

14. The context-adaptive VLC apparatus of claim 5, wherein the internal total coefficient number storage comprises:
a plurality of left buffers, each of which is configured to store a total coefficient number of the left side blocks of the selected macroblock including the selected block; and
a plurality of upper buffers, each of which is configured to store a total coefficient number of the upper side blocks of the selected macroblock including the selected block.

15. The context-adaptive VLC apparatus of claim 14, wherein the coefficient information generator is configured to transmit the total coefficient number of the selected block and total coefficient numbers of blocks at the left and upper sides of the selected block to the bit data generation unit when the total coefficient number of the selected block is calculated, and to update the total coefficient numbers of the blocks at the left and upper sides of the selected block with the total coefficient number of the selected block.

16. The context-adaptive VLC apparatus of claim 14, wherein, if the selected block is the first block of the selected macroblock, the coefficient information generator is configured to read total coefficient numbers of the blocks of an upper macroblock from the total coefficient number storage unit and to store the total coefficient numbers of the blocks of an upper macroblock in the internal total coefficient number storage before calculating the total coefficient number of the selected block; and
if the selected block is the last block of the selected macroblock, the coefficient information generator stores the total coefficient numbers stored in the internal total coefficient number storage in the total coefficient number storage unit after calculating the total coefficient number of the selected block.

17. The context-adaptive VLC apparatus of claim 2, wherein the total coefficient numbers of the blocks of the upper macroblock are stored in the upper buffers of the internal total coefficient number storage.

18. The context-adaptive VLC apparatus of claim 1, wherein the bit data generation unit is configured to convert the coefficient information of the selected block into bit data with reference to a group of tables selected based on the coefficient information of the selected block.

19. The context-adaptive VLC apparatus of claim 18, wherein the group of tables comprises a total coefficient number table used for coding the total coefficient number of the selected block and a level table used for coding level values of the selected block,
wherein the total coefficient number table is selected based on the total coefficient numbers of the previous block and the blocks at the left and upper sides of the previous block, and the level table is selected based on the level values of the selected block.

20. A context-adaptive variable length coding (VLC) method for variable length coding coefficients of a blocks of a selected macroblock of image data, comprising:
in response to an information generation control signal, generating coefficient information used for coding coefficients of a selected block that is read out of the selected macroblock; and
in response to a bit generation control signal, coding coefficient information of a block previous to the selected block generated in advance by the coefficient information generation unit,
wherein generating the coefficient information of the selected block and coding the coefficient information of the previous block are performed in parallel.

21. The context-adaptive VLC method of claim 20, wherein the coefficient information of the selected or previous block comprises a trailing ones number, a level value, and a run value of the selected or previous block.

22. The context-adaptive VLC apparatus of claim 20, wherein generating the coefficient information of the selected block comprises:
reading the coefficients of the selected block by following an inverse zigzag course;
determining whether a selected coefficient currently being read out from the selected block has a value of 0;
increasing the run value of the selected block if the selected coefficient has a value of 0, and calculating the coefficient information of the selected block, except for the run value, based on the value of the selected coefficient if the selected coefficient has a value other than 0; and
storing the total coefficient number, the trailing ones number, the level value, the run value, and a total zeros number of the selected block if reading of the coefficients of the selected block is complete.

23. The context-adaptive VLC method of claim 22, wherein the calculating the coefficient information of the selected block except for the run value comprises:
increasing the total coefficient number and determining whether the selected coefficient has an absolute value of 1;
resetting a trailing ones valid flag and then determining whether a coefficient valid flag is set if the selected coefficient does not have an absolute value of 1 and calculating the trailing ones number and then determining whether the coefficient valid flag is set if the selected coefficient has an absolute value of 1; and
setting the coefficient valid flag, updating the level value with the value of the selected coefficient, and resetting the run value if the coefficient valid flag is yet to be set and storing the level value and the run value, updating the level value with the value of the selected coefficient, and resetting the run value if the coefficient valid flag is already set,
wherein storing the total coefficient number, the trailing ones number, the level value, the run value, and the total zeroes number of the selected block further comprises resetting the coefficient valid flag.

24. The context-adaptive VLC method of claim 23, wherein calculating the trailing ones value comprises:
responsive to a determination that the absolute value of the selected coefficient is 1, setting the trailing ones valid flag and increasing the trailing ones number if a coefficient having an absolute value of 1 has not yet been read out from the selected block;
determining whether a coefficient previous to the selected coefficient has an absolute value of 1 and deciding whether to increase or maintain the trailing ones number based on the trailing ones valid flag and the trailing ones number if a coefficient having an absolute value of 1 has already been read out from the selected block,
wherein deciding whether to increase or maintain the trailing ones number comprises:
increasing the trailing ones number if the previous coefficient has an absolute value of 1, the trailing ones valid flag is already set, and the trailing ones number does not exceed 3;
resetting the trailing ones valid flag and maintaining the trailing ones number if the previous coefficient does not have an absolute value of 1; and
maintaining the trailing ones number if the previous coefficient has an absolute value of 1 and the trailing ones valid flag is not set or if the previous coefficient has an absolute value of 1, the trailing ones valid flag is already set, and the trailing ones number is not less than 3.

25. The context-adaptive VLC method of claim 22, wherein storing the total coefficient number of the selected block comprises:
determining whether the selected block is the first block of the selected macroblock;
calculating the total coefficient number of the selected block if the selected block is not the first block of the selected macroblock and reading total coefficient numbers of blocks of an other macroblock at the upper side of the selected macroblock, storing the read total coefficient numbers in an internal memory, and calculating the total coefficient number of the selected block if the selected block is the first block of the selected macroblock;
storing the total coefficient number of the selected block in the internal memory so that a total coefficient number previously stored in the internal memory can be replaced with the total coefficient number of the selected block; and
storing a group of total coefficient numbers stored in the internal memory if the selected block is the last block of the selected macroblock.

26. The context-adaptive VLC method of claim 20, wherein coding the coefficient information of the previous block comprises:
coding the total coefficient number of the previous block with reference to a total coefficient number table selected based on the total coefficient number of the previous block and total coefficient numbers of blocks at the left and upper sides of the previous block;
coding level values of the previous block with reference to a level table selected based on the level values of the previous block;
coding a total zeros number of the previous block with reference to a predetermined table selected based on the total coefficient number of the previous block; and
coding run values of the previous block.

27. A computer program product for performing context-adaptive variable length coding of coefficients of a blocks of a selected macroblock of image data, the computer program product comprising:
a computer readable storage medium having computer readable program code embodied in said medium, said computer readable program code comprising:
computer readable program code configured to generate, in response to an information generation control signal, coefficient information used for coding coefficients of a selected block that is read out of the selected macroblock; and
computer readable program code configured to code, in response to a bit generation control signal, coefficient information of a block previous to the selected block generated in advance by the coefficient information generation unit,
wherein generating the coefficient information of the selected block and coding the coefficient information of the previous block are performed in parallel.
